(19) United States
(12) Patent Application Publication
(10) Pub. No.: US 2014/0324368 A1
(43) Pub. Date: Oct. 30, 2014

(54) TEST METHOD, TEST SYSTEM AND ELECTRONIC DEVICE EMPLOYING THE SAME

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventor: GUANG-JIAN WANG, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/265,469

(22) Filed: Apr. 30, 2014

(30) Foreign Application Priority Data
Apr. 30, 2013 (CN) 201310155521X

(51) Int. Cl. G01R 31/28

(52) U.S. Cl. CPC G01R 31/2834
USPC 702/57

(57) ABSTRACT

A test method for an electronic device is provided. The method includes the following steps. A test file is obtained from a main server. The electronic device is tested according to the test file and a test result is generated. The test result is output to an interface of the electronic device that can be accessed by the main server. The main server polls the test result from the interface of the electronic device each time a predetermined time duration elapses. An electronic device with testing function and a test system are also provided.

### FIELD

The present disclosure relates to a test method, a test system, and an electronic device employing the same.

### BACKGROUND

Electronic devices that need to be tested are connected to a main server. During the test process, data is transmitted between the main server and the electronic device via the Internet.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts or sections throughout the drawings.

FIG. 1 illustrates an environment of a test system in accordance with an embodiment of the present disclosure.

FIG. 2 is a block diagram of the test system of FIG. 1, in accordance with the embodiment of the present disclosure.

FIG. 3 is a flowchart of a test method in accordance with an embodiment of the present disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”. The references “a plurality of” and “a number of” mean “at least two.”

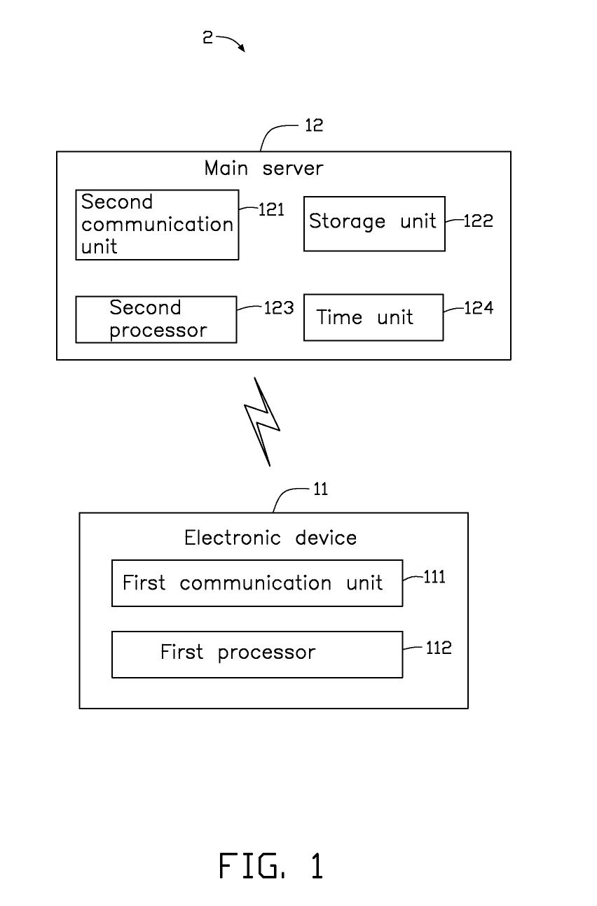

FIG. 1 illustrates an application environment of a test system 2 in accordance with an embodiment of the present disclosure. The test system 2 can run on at least one electronic device 11 and a main server 12. The electronic device 11 can be a tablet personal computer, a telephone, an e-reader, for example. The main server 12 can be a computer host, a server, a personal computer, for example.

Each electronic device 11 can include a first communication unit 111 and a first processor 112. The main server 12 can include a second communication unit 121, a storage unit 122 and a second processor 123 and a time unit 124. The main server 12 can be coupled to each electronic device 11 via the second communication unit 121. The storage unit 122 can store a number of test files for testing each electronic device 11.

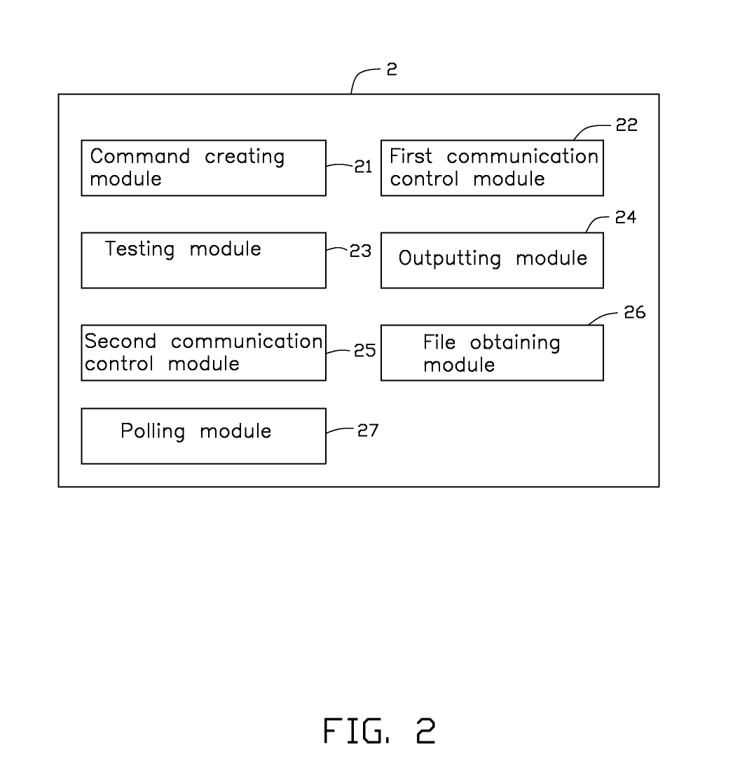

FIG. 2 illustrates a block diagram of the test system of FIG. 1. The test system 2 can include a number of function modules, a portion of which run on the electronic devices 11, and a portion of which run on the main server 12.

In the embodiment, the function modules can further include a command creating module 21, a first communication control module 22, a testing module 23, and an outputting module 24 which are executable by the first processor 112 of the each of the electronic devices 11. The function modules of the test system 2 can further include a second communication control module 25, a file obtaining module 26, and a polling module 27 which are executable by the second processor 123 of the main server 12. In other embodiments, the function modules of the test system 1 may be a collection of software instructions, executable by the first processor 112 of each electronic device 11 and the second processor 123 of the main server 12.

When the main server 12 is coupled to one of the electronic devices 11 without a test file (hereinafter “the requesting electronic device 11”), the command creating module 21 can control the requesting electronic device 11 to create a command for obtaining a test file for testing the requesting electronic device 11. The test file can include all the files that are needed for testing the requesting electronic device 11.

The first communication control module 22 can be used for controlling the first communication unit 111 to transmit the command created by the command creating module 21 to the main server 12.

The file obtaining module 26 can be used for controlling the main server 12 to obtain the test file from the storage unit 122 when the command is received.

The second communication control module 25 can be further used for controlling the second communication unit 121 of the main server 12 to transmit the test file to the requesting electronic device 11.

The testing module 23 can be used for controlling the first processor 112 of the requesting electronic device 11 to test the requesting electronic device 11 according to the test file and generating a test result when the test file is received. In at least one embodiment, the testing module 23 can test whether the configuration of the requesting electronic device 11 is correct. The testing module 23 can also test whether the performance of the electronic device has reached a pre set standard. For example, if a given capacity of the requesting electronic device 11 is 500 G, and the actual tested capacity of the requesting electronic device 11 is 200 G, the testing module 23 determines that the configuration of the requesting electronic device 11 is not correct. In another example, if a given processing speed of the requesting electronic device 11 is 1 GHZ/s, and the actual tested processing speed of the first processor 112 of the requesting electronic device 11 is 1 MHZ/s, the testing module 23 determines that the performance of the first processor 112 is not eligible.

The outputting module 24 can be used for controlling the requesting electronic device 11 to transmit the test result to an interface such as a web service of the requesting electronic device 11. The interface is an external interface that can be accessed by the main server 12.

The polling module 27 can be used for controlling the main server 12 to poll the interface of the each of the electronic device 11 to obtain the test results when the time unit 124 has timed to a predetermined time duration.

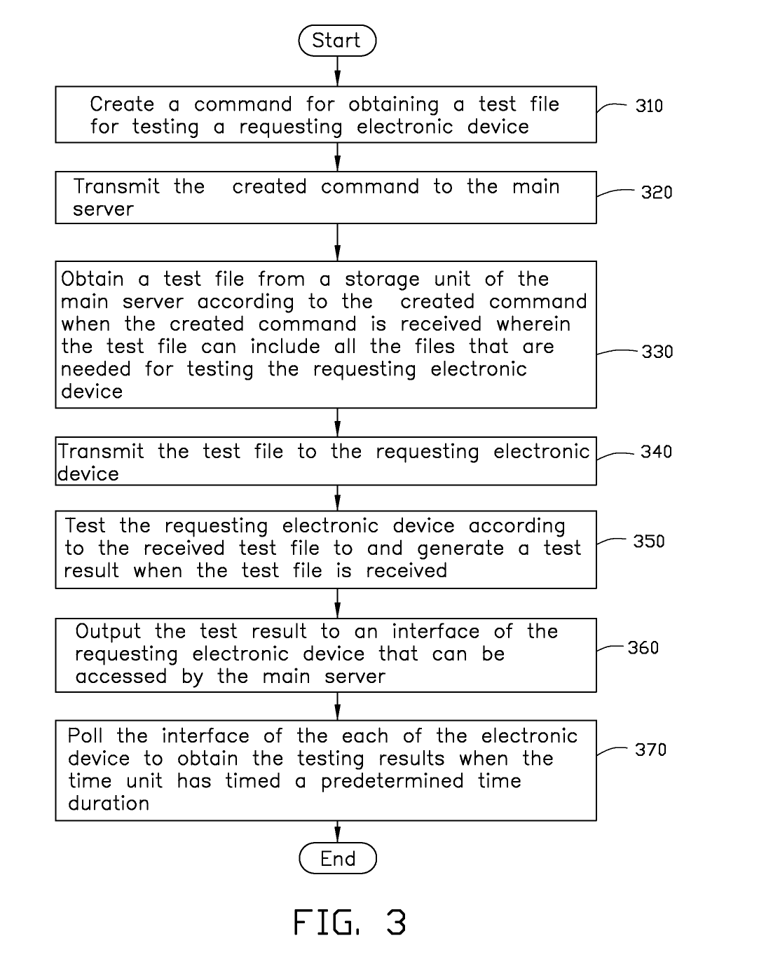

FIG. 3 illustrates a flowchart of a method for testing one or more electronic devices.

In block 310, the command creating module can control the requesting electronic device to create a command for obtaining a test file for testing the requesting electronic device.

In block 320, the first communication control module can control the first communication unit of the requesting electronic device to transmit the created command to the main server.

In block 330, the file obtaining module controls the main server to obtain a test file from the storage unit according to the created command when the created command is received In at least one embodiment, the test file can include all the files that are needed for testing the requesting electronic device.

In block 340, the second communication control module can control the second communication unit to transmit the test file to the requesting electronic device.

In block 350, the testing module can control the first processor of the requesting electronic device to test the requesting electronic device according to the test file and generate a test result when the test file is received.

In block 360, the outputting module can control the requesting electronic device to output the test result to an interface of the requesting electronic device such as a web service that can be accessed by the main server.

In block 370, the polling module can control the main server to poll the interface of the each electronic device to obtain the test results when the time unit has timed a predetermined time duration.

Although the present disclosure has been specifically described on the basis of various embodiments thereof, the disclosure is not to be construed as being limited thereto. Various changes or modifications may be made to the embodiments without departing from the scope and spirit of the disclosure.

What is claimed is:

1. An electronic device, comprising:
a communication unit;
a communication control module to control the communication unit to receive a test file transmitted from a main server;
a testing module to test the electronic device according to the received test file and generate a test result;
an output module to control the electronic device to output the test result to an interface of the electronic device that can be accessed be the main server.

2. The electronic device of claim 1, further comprising a command creating module to control the electronic device to create a command for obtaining a test file for testing the electronic device, wherein the communication control module is further configured to control the communication unit to transmit the created command to the main server.

3. A test method applied on an electronic device, the method comprising:
receiving a test file transmitted from a main server;
testing the electronic device according to the test file and generating a test result;.
outputting the test result to an interface of the electronic device that can be accessed by the main server.

4. The test method as described in claim 3, further comprising a step before receiving a test file transmitted from a main server, the step comprising:
creating a command for obtaining a test file for testing the electronic device and transmitting the command to the main server.

5. A test system, which is run on a main server and at least one electronic device, wherein each electronic device comprises a first communication unit, and the main server comprises a second communication unit, the system comprising:
a first communication control module to control the first communication unit to receive a test file transmitted from the main server;
a testing module to test the electronic device according to the test file and generate a test result;
an outputting module to control the electronic device to output the test result to an interface of the electronic device that can be accessed by the main server; and
a polling module to poll the interface of the each of the electronic device to obtain the test results each time a predetermined time duration elapses.

6. The test system as described in claim 5, further comprising:
a second communication control module to control the second communication unit of the main server to receive the created command and transmit the test file to the electronic device;
a file obtaining module to obtain the test file according to the created command and the test file includes all the files that are needed for testing a requesting electronic device.

7. The test system as described by claim 5, wherein the first communication control module, the testing module, and the outputting module are applied on the each of the electronic device; the first communication control module, the file obtaining module and the polling module are applied on the main server.
